(19) United States
(12) Patent Application Publication
(10) Pub. No.: US 2026/0057159 A1
(43) Pub. Date: Feb. 26, 2026

(54) MEMORY MODEL BUILDING METHOD AND MEMORY CIRCUIT SIMULATION METHOD

(71) Applicant: Winbond Electronics Corp., Taichung City (TW)

(72) Inventors: Chia-Lung Lin, Taichung City (TW); Chih-Hao Cheng, Taichung (TW); Chao-Lung Wang, Taichung City (TW); Kang Ming Peng, Taichung City (TW); Cheng Han Lee, Taichung City (TW)

(73) Assignee: Winbond Electronics Corp., Taichung City (TW)

(21) Appl. No.: 19/306,975

(22) Filed: Aug. 21, 2025

(30) Foreign Application Priority Data
Aug. 22, 2024 (TW) 113131645

(51) Int. Cl. G06F 30/3308; G06F 30/333

(52) U.S. Cl. CPC G06F 30/3308; G06F 30/333

(57) ABSTRACT

Disclosed is a memory model building method and a memory circuit simulation method. The memory model building method includes the following steps. A test condition is applied to unselected memory cells in a memory string. A threshold voltage of a selected memory cell in the memory string is programmed to a first threshold voltage value. Tests are performed on the memory cell string by setting the test condition as test values so as to obtain first impedance values corresponding to the test values. The test values and the corresponding first impedance values are analyzed so as to obtain a linear model having a first slope value and a first intercept value. A relationship between the test values and the corresponding first impedance values at the first threshold voltage value satisfies the linear model.

### CROSS-REFERENCE TO RELATED APPLICATION

This application claims the priority benefit of Taiwan application serial no. 113131645, filed on Aug. 22, 2024. The entirety of the above-mentioned patent application is hereby incorporated by reference herein and made a part of this specification.

### BACKGROUND

### Technical Field

The disclosure relates to a method, and in particular to a memory model building method and a memory circuit simulation method.

### Description of Related Art

In general, when reading NAND flash memory, which is connected in series, a read voltage is applied to the selected memory cell, and a pass voltage is applied to the unselected memory cells to read the data value stored in the selected memory cell. However, due to the series connection, the value read from the selected memory cell is also affected by the impedance value of other unselected memory cells. In addition, the current flowing through the memory string is affected by temperature. Therefore, to simulate the memory circuit during the development of flash memory, SPICE models are used to describe the parameters (e.g., parameters related to temperature effects or pass voltage effects) needed for simulation. For example, by measuring and establishing the current-voltage characteristic curve of the transistor of the selected memory cell, and affecting the current-voltage characteristic curve of the transistor of the selected memory cell through the change in the pass voltage applied to the unselected memory cells, parameters related to the pass voltage effect needed for the simulation can be obtained.

However, to simulate different threshold voltages, in the prior art, generating multiple SPICE models is required. Each SPICE model describes the parameters needed for simulation and corresponding to different threshold voltages. As a result, developers of flash memory need to maintain numerous SPICE models, increasing the complexity of the simulation. Furthermore, as shown in FIG. 1, to generate multiple SPICE models corresponding to different threshold voltages, in the prior art, the current-voltage characteristic curve (referred to as the first SPICE model) of the first threshold voltage during the change in the pass voltage applied to the unselected memory cells is only shifted to the left to generate the second SPICE model related to the second threshold voltage. Alternatively, in the prior art, the first SPICE model is only shifted to the right to generate the third SPICE model related to the third threshold voltage. This way, the accuracy of the simulation provided by these SPICE models still needs improvement, resulting in challenges in reducing development time and cost.

### SUMMARY

The disclosure provides a memory model building method and a memory circuit simulation method to simulate a memory circuit behavior with a fast and accurate circuit model.

A memory model building method of the disclosure includes the following steps. A test condition is applied to a plurality of unselected memory cells in a memory string. A threshold voltage of a selected memory cell in the memory string is programmed to a first threshold voltage value. Multiple tests are performed on the memory cell string by setting the test condition as multiple test values so as to obtain multiple first impedance values respectively corresponding to the test values. The test values and the respectively corresponding first impedance values are analyzed so as to obtain a linear model having a first slope value and a first intercept value. A relationship between the test values and the respectively corresponding first impedance values at the first threshold voltage value satisfies the linear model.

A memory circuit simulation method of the disclosure is for simulating a circuit behavior of a memory string having multiple unselected memory cells and a selected memory cell. The memory circuit simulation method includes the following steps. A preset threshold voltage value is received. A slope value and an intercept value is obtained according to the preset threshold voltage value. The slope value and the intercept value are converted into a linear model. The linear model records a corresponding relationship between a test value provided to the plurality of unselected memory cells in the memory string and an impedance value of the memory string at the preset threshold voltage value.

Based on the above, the memory model building method and the memory circuit simulation method of the disclosure can extract multiple coefficients—such as slope and intercept values—from the relationship between the test conditions applied to unselected memory cells in a memory string and the impedance values measured when a selected memory cell is programmed to a specific threshold voltage. These coefficients are used to build a linear model that represents the behavior of the memory string under the given threshold voltage. The simulation method then utilizes the linear model to simulate the circuit behavior of the memory string. Therefore, simulation of the circuit behavior of the memory can be done efficiently and accurately, with reduced model complexity and improved scalability.

### BRIEF DESCRIPTION OF THE DRAWINGS

FIG. 1 is a schematic diagram of multiple SPICE models known in the art.

FIG. 2 is a circuit diagram of a memory string according to the embodiment of the disclosure.

FIGS. 3A and 3B are flowcharts of memory model building methods according to the embodiment of the disclosure.

FIG. 4A is a schematic diagram of multiple linear models of impedance values of a memory string MS and test voltages under different threshold voltage values of a selected memory cell according to an embodiment of the disclosure.

FIG. 4B is a schematic diagram of an exponential relationship between slope values of a line in FIG. 4A and threshold voltage values of a selected memory cell.

FIG. 4C is a schematic diagram of an exponential relationship between intercept values of the line in FIG. 4A and threshold voltage values of the selected memory cell.

FIG. 4D is a schematic diagram of multiple memory models according to the embodiments of the disclosure.

FIGS. 5A to 5C are flowcharts of memory circuit simulation methods according to the embodiment of the disclosure.

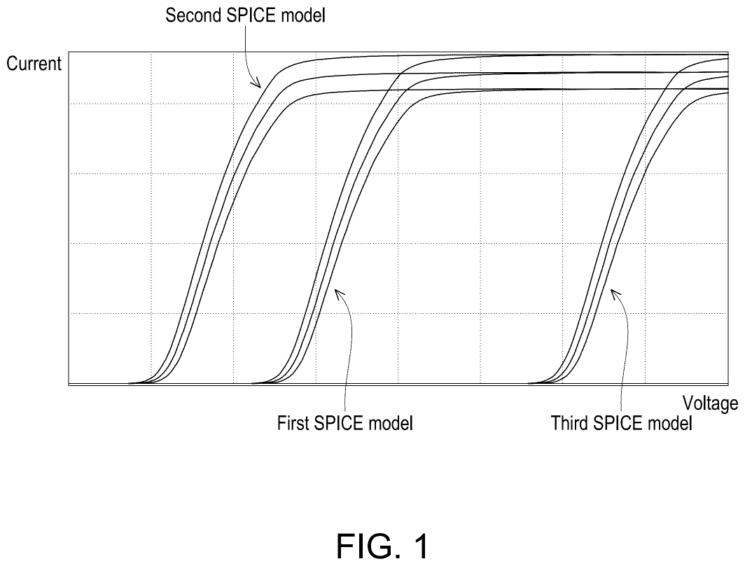

### DESCRIPTION OF THE EMBODIMENTS

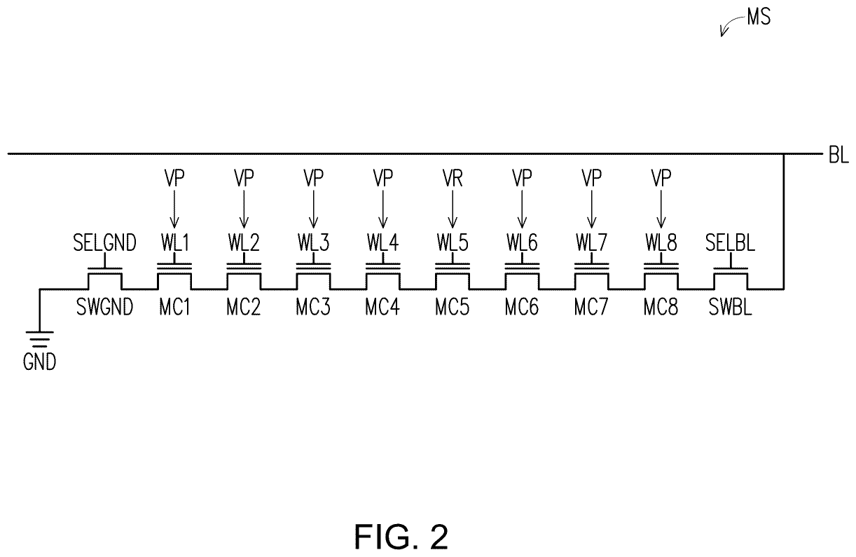

FIG. 2 is a circuit diagram of a memory string MS according to the embodiment of the disclosure. The memory string MS may be, for example, a NAND flash memory. The memory string MS includes a switch SWBL, memory cells MC1 to MC8, and a switch SWGND connected in series between a bit line BL and a reference ground voltage GND. The switches SWBL and SWGND are turned on or turned off through the control by select signal lines SELBL and SELGND, thereby controlling the overall operation of the memory string MS. Each of the memory cells MC1 to MC8 may receive corresponding signals through word lines WL1 to WL8 and the bit line BL to perform programming and/or erasing operations, so that the threshold voltage of each of the memory cells MC1 to MC8 is controlled at a corresponding voltage value, thereby storing data.

In an embodiment, when data stored in a selected memory cell from MC1 to MC8 needs to be read, a read voltage VR may be applied to the word line of the selected memory cell, and a pass voltage may be applied to the word lines of the other unselected memory cells in the memory string. For example, in FIG. 2, if the memory cell MC5 is selected to read the data stored therein, the read voltage VR may be applied to the word line WL5 connected to the selected memory cell MC5, and a pass voltage VP may be applied to the word lines WL1 to WL4 and WL6 to WL8 connected to the other unselected memory cells MC1 to MC4 and MC6 to MC8 in the memory string MS. This way, the read circuit in the memory system may read the current or impedance value flowing through the memory string MS via the bit line BL, thereby determining the data value stored in the selected memory cell MC5.

During the read operation, the current or impedance value flowing through the memory string MS is affected by the threshold voltage of the selected memory cell MC5 and is restricted to one of multiple corresponding value ranges. The read circuit may determine which value range the sensed current or impedance value falls into, thereby determining the data value stored in the selected memory cell MC5. However, the current flowing through the memory string MS not only flows through the selected memory cell MC5, but also flows through the other unselected memory cells MC1 to MC4 and MC6 to MC8. In other words, the read operation for the selected memory cell MC5 is not only affected by the programmed threshold voltage of the selected memory cell MC5, but also by the impedance values of the unselected memory cells MC1 to MC4 and MC6 to MC8. More specifically, the impedance values of the unselected memory cells MC1 to MC4 and MC6 to MC8 are shifted due to the effect of the voltage value of the pass voltage VP applied thereon. When the impedance values of the unselected memory cells MC1 to MC4 and MC6 to MC8 are over-shifted, the current flowing through the memory string MS exceeds the current range corresponding to the data value stored in the selected memory cell MC5, thus generating a read error in the memory string MS.

Additionally, the current flowing through the memory string MS is also affected by temperature.

Therefore, in the embodiment of the disclosure, memory model building methods and memory circuit simulation methods are provided to reduce the number of SPICE models that need to be maintained and to more accurately capture the parameters required for simulation (e.g., parameters related to temperature effects or pass voltage effects) more accurately, thereby shortening the development time of flash memory and reducing read errors.

Moreover, the memory string MS illustrated in FIG. 2 is provided for illustrative purposes and does not limit the hardware implementation of the memory string MS. A person having ordinary skill in the art may adjust or modify the number of memory cells in the memory string MS or the target of the selected memory cell according to different design requirements.

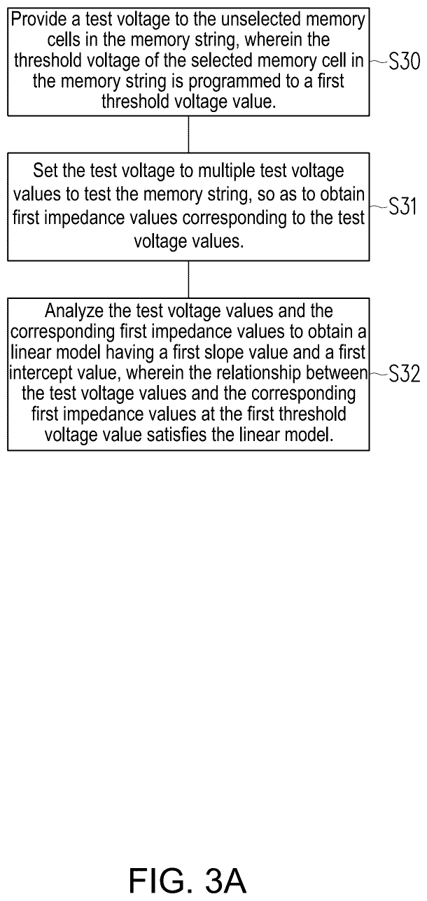

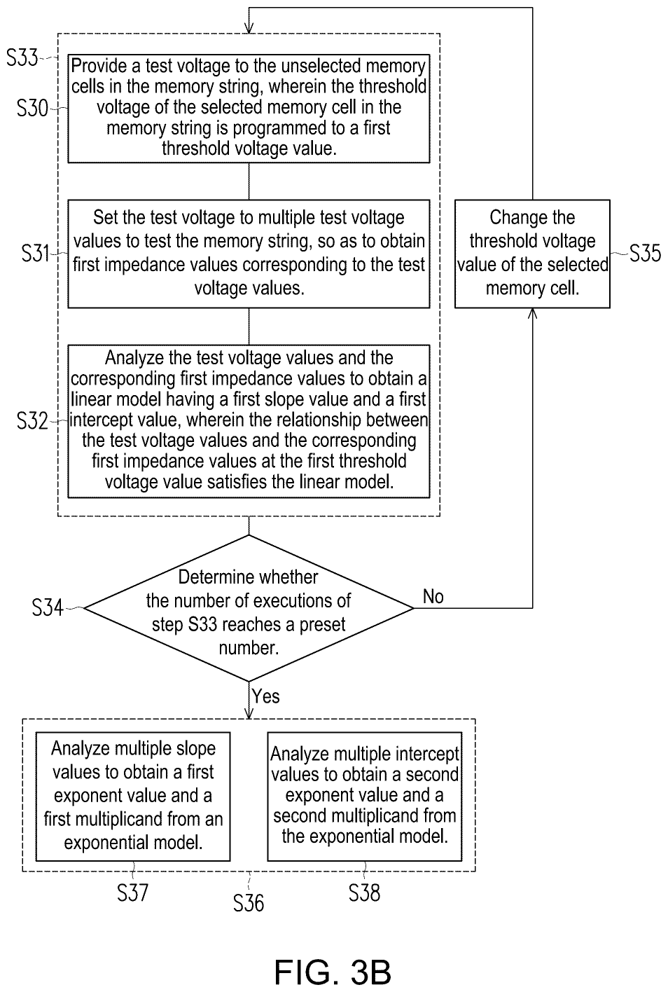

FIGS. 3A and 3B are flowcharts of a memory model building method according to the embodiment of the disclosure. The memory model building method in this embodiment may be applied to the memory string MS shown in FIG. 2, or to a memory system that includes the memory string MS shown in FIG. 2, thereby building a circuit model compatible with general or specific circuit simulation software. For example, the circuit model generated through the memory model building method may be compatible with general circuit simulation software such as the Simulation Program with Integrated Circuit Emphasis (SPICE) or similar circuit software like H-Spice, P-Spice, Cadence, or Advanced Design System (ADS).

In an embodiment of this disclosure, the memory model building method may build a first prediction model by applying different pass voltages VP to the unselected memory cells MC and measuring the corresponding current value of the memory string MS, thereby establishing a relationship between the pass voltage VP and the current value. More specifically, the first prediction model is, for example, a linear model, and the disclosure uses the corresponding relationship between the parameters (e.g., the slope value or the intercept value) of the first prediction model and the different threshold voltage values of the selected memory cell in the memory string MS to build a second prediction model. The second prediction model is used to predict the slope value or the intercept value of the corresponding relationship between the pass voltage VP and the current values of the memory string MS under specific threshold voltage values. In this embodiment, the second prediction model is a linear model. Additionally, through this method, the test voltage provided during testing is the pass voltage, as previously mentioned.

Furthermore, in another embodiment of the disclosure, through the memory model building method, a first prediction model may be constructed by applying different test temperatures to the memory string MS and measuring the corresponding current value, thereby establishing a relationship between the test temperature and the current value. Moreover, the disclosure may use the corresponding relationship between the parameters (e.g., the slope value or the intercept value) of the first prediction model and the different threshold voltage values of the selected memory cell in the memory string MS to establish the second prediction model, which is used to predict the parameters of the first prediction model under specific threshold voltage values.

Next, in this embodiment, the first prediction model and the second prediction model are recorded in a SPICE model to facilitate subsequent memory circuit simulation. The test condition may involve changes in pass voltage or test temperature, but the disclosure is not limited thereto.

Specifically, as shown in FIG. 3A, the memory model building method of the disclosure includes steps S30 to S32. Referring to FIG. 2, in step S30, when the threshold voltage of the selected memory cell MC5 in the memory string MS is programmed to a first threshold voltage value, a test voltage (i.e., the pass voltage VP) may be provided to the unselected memory cells MC1 to MC4 and MC6 to MC8 in the memory string MS. At the same time, the read voltage VR is also provided to the selected memory cell MC5 to facilitate the subsequent read operation.

In step S31, by setting the test voltage to multiple test voltage values to test the memory string MS, first impedance values corresponding to the test voltage values are obtained. Specifically, in step S31, all unselected memory cells MC1 to MC4 and MC6 to MC8 receive the same test voltage value, allowing the measurement and recording of the first impedance value of the memory string MS. Further, after changing the test voltage value provided to the unselected memory cells MC1 to MC4 and MC6 to MC8, the above testing process may be repeated to measure and record the first impedance value of the memory string MS corresponding to the changed test voltage value.

In step S32, the multiple test voltage values provided in step S31 and the measured first impedance values may be analyzed to obtain and record the corresponding relationship between the test voltage values and the corresponding first impedance values of the memory string MS under the condition where the selected memory cell MC5 is programmed at the first threshold voltage value, and build the first prediction model accordingly. More specifically, the corresponding relationship between the test voltage values and the corresponding first impedance values may be linear, which may be shown using the corresponding slope values and intercept values. Therefore, in step S32, the slope value and the intercept value of the first prediction model built according to the corresponding relationship between the test voltage values and the corresponding first impedance values may be stored in the SPICE model.

More specifically, at the first threshold voltage value, the first prediction model built according to the test voltage values and the corresponding first impedance values may be:

$$R = P 1 \times V pass + P 2$$

wherein R corresponds to the first impedance value, Vpass corresponds to the test voltage value, P1 corresponds to the first slope value, and P2 corresponds to the first intercept value.

As shown in FIG. 3B, in addition to steps S30 to S32 described in FIG. 3A being executed as a part of step S33, the memory model building method of the disclosure further includes steps S34 to S38. In general, in this embodiment, the threshold voltage value of the selected memory cell may be changed and steps S30 to S32 in FIG. 3A may be repeated to obtain multiple first prediction models of the selected memory cell at different threshold voltage values. Specifically, in the initial state, the threshold voltage of the selected memory cell M5 may be, for example, programmed to the first threshold voltage value, and after step S33 is first completed, the first prediction model corresponding to the first threshold voltage value is obtained. In step S34, it is determined whether the number of times step S33 has been executed has reached a preset number. If not (i.e., the step S33 execution count is less than the preset number), the threshold voltage value of the selected memory cell is changed (step S35), and the process returns to step S33 to build another linear model. Once the preset number of step S33 executions is reached, the method proceeds to step S36, where the relationship between the parameters (e.g., slope and intercept values) of the previously built linear models and the corresponding threshold voltages is analyzed to construct a second prediction model. The preset number may be set to two or more.

According to step S35, after the threshold voltage value of the selected memory cell MC5 is changed (e.g., from the first threshold voltage value to a second threshold voltage value), the process returns to step S33. This allows the construction of another first prediction model that reflects the relationship between the test voltage and the impedance of the memory string MS when the selected memory cell MC5 is programmed to the second threshold voltage.

In an embodiment, the process of building the second prediction model (step S36) includes steps S37 and S38. Step S37 involves analyzing the corresponding relationship between the first parameters (e.g., the slope values) of the multiple first prediction models and the different threshold voltage values, and step S38 involves analyzing the corresponding relationship between the second parameters (e.g., the intercept values) of the multiple first prediction models and the different threshold voltage values. Steps S37 and S38 may be executed at the same time or executed in an appropriate sequence according to the requirements. These execution sequences fall within the scope of variant embodiments.

In this embodiment, in step S37, an analysis of the corresponding relationship between the multiple slope values of the first prediction models and the different threshold voltage values is performed to build an exponential model having a first exponent value and a first multiplicand (as shown in the following example).

$$PX = C 1 \times {e}^{Vt \times C 2}$$

Here, PX corresponds to the slope value of the first prediction model at the first threshold voltage value or the second threshold voltage value, C1 corresponds to the first multiplicand, Vt corresponds to the first threshold voltage value or the second threshold voltage value, and C2 corresponds to the first exponent value. In this embodiment, by substituting the first and second threshold voltage values (the number of which depends on the aforementioned preset number of executions) and their corresponding slope values of the first prediction model into the above exponential model, the corresponding first multiplicand and first exponent value can be obtained.

In this embodiment, in step S38, an analysis of the corresponding relationship between the multiple intercept values of the first prediction models and the different threshold voltage values is performed to build an exponential model with a second exponent value and a second multiplicand (as shown in the following example).

$$PX = C 3 \times {e}^{Vt \times C 4}$$

Here, PX corresponds to the intercept value of the first prediction model at the first threshold voltage value or the second threshold voltage value, C3 corresponds to the second multiplicand, Vt corresponds to the first threshold voltage value or the second threshold voltage value, and C4 corresponds to the second exponent value. In this embodiment, by substituting the first and second threshold voltage values (the number of which depends on the aforementioned preset number of executions) and their corresponding intercept values of the first prediction model into the above exponential model, the corresponding second multiplicand and second exponent value can be obtained.

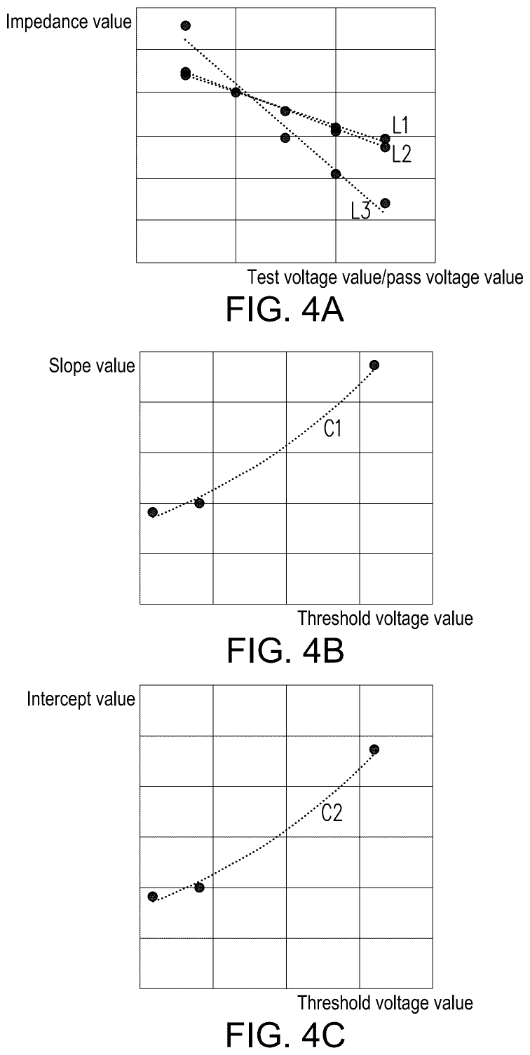

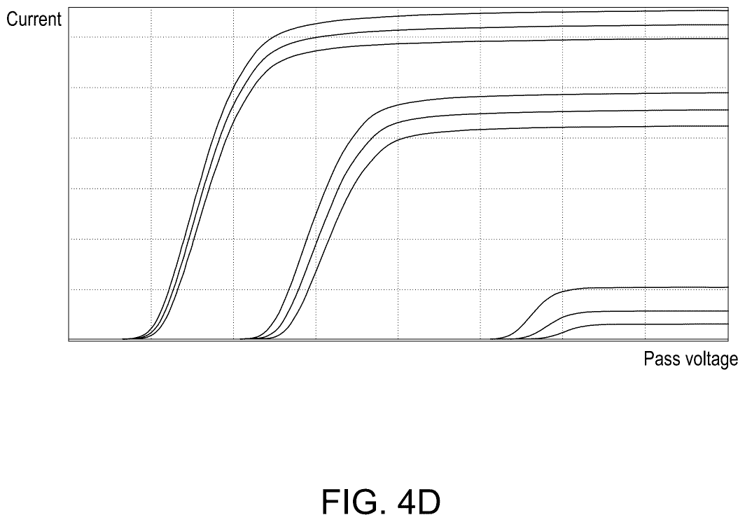

Next, FIGS. 4A to 4C will be used as examples to describe the memory model building method illustrated in FIGS. 3A and 3B. FIG. 4A is a schematic diagram of multiple linear models of impedance values of the memory string MS and test voltages under different threshold voltage values of the selected memory cell MC5 according to an embodiment of the disclosure.

Specifically, after steps S30 to S32 (i.e., step S33) are completed, the linear model representing the relationship between the impedance values of the memory string MS and the test voltages can be obtained. By repeatedly executing the loop formed by steps S33 and S35, multiple linear models that characterize the relationship between the test voltages and the impedances of the memory string MS under different threshold voltage values can be constructed.

FIG. 4A shows lines L1 to L3, respectively representing the linear models of the impedance values of the memory string MS and the test voltages under different threshold voltage values of the selected memory cell MC5. For example, line L1 represents the linear model when the selected memory cell MC5 stores a data value of 0 at a threshold voltage of −4.5V. Line L2 represents the linear model when the selected memory cell MC5 stores a data value of 0 at a threshold voltage of −2.5V. Line L3 represents the linear model when the selected memory cell MC5 stores a data value of 1 at a threshold voltage of 4.7V.

After obtaining a sufficient number of linear models, the process proceeds to step S36 to analyze how the slope values and intercept values of these linear models vary with the threshold voltage values of the selected memory cell MC5. As shown in FIG. 4B, an exponential model C1 with a first multiplicand and a first exponent value may be built according to the exponential or logarithmic distribution of the slope values of lines L1 to L3 in FIG. 4A with respect to their corresponding threshold voltage values. Therefore, by substituting the slope values and the corresponding threshold voltage values into the exponential model C1, the first multiplicand and the first exponent value may be derived.

As shown in FIG. 4C, an exponential model C2 with a second multiplicand and a second exponent value may be built according to the exponential or logarithmic distribution of the intercept values of lines L1 to L3 in FIG. 4A with respect to their corresponding threshold voltage values. Therefore, by substituting the intercept values and the corresponding threshold voltage values into the exponential model C2, the second multiplicand and the second exponent value may be derived.

The memory model illustrated in FIG. 4D is obtained through the memory model building method in FIG. 3A or FIG. 3B. For example, the memory model illustrated in FIG. 4D may be obtained by taking the reciprocal of the impedance values shown in FIG. 4A.

As shown in FIG. 4D, for each linear memory model built through the method in FIG. 3A or FIG. 3B, not only is the current turned on at different threshold voltage values, the saturation region current after being turned on also differs. This way, the memory model built through the method in FIG. 3A or FIG. 3B may record the circuit behavior of the memory more precisely using smaller memory space, thereby effectively improving the overall time required for the circuit design process and the accuracy of the simulation results.

In simple terms, the memory model building method illustrated in FIG. 3B allows repeated testing of the memory string under different threshold voltages of the selected memory cell, thereby generating multiple linear models that describe the relationship between the test voltages (or pass voltages) and the corresponding impedance values of the memory string. More specifically, the linear models are shown and stored using slope values and intercept values. Further, the slope values and the intercept values may be further analyzed to obtain the exponential models that describe how the slope and intercept vary with the threshold voltages of the selected memory cell. More specifically, the bases of the two exponential models may be the same and derived from the same preset exponential model. Therefore, the memory model building method ultimately only needs to store the first multiplicand, the first exponent value, the second multiplicand, the second exponent value, and the preset exponential model to represent all the linear models describing the relationship between the impedance values of the memory string MS and the test/pass voltages across various threshold voltage values. This reduces the storage requirements for the memory models, shortens simulation time, and improves simulation accuracy.

In an embodiment, the memory model building method described in FIGS. 3A and 3B may be realized using a computer device, and the computer device may include a processor and memory. The computer device may be coupled to the target memory via a testing platform or a probe card to obtain the impedance value of the memory string MS. Alternatively, the impedance value of the memory string may be tested and stored in advance, and then be provided to the computer device that performs the memory model building method in FIGS. 3A and 3B.

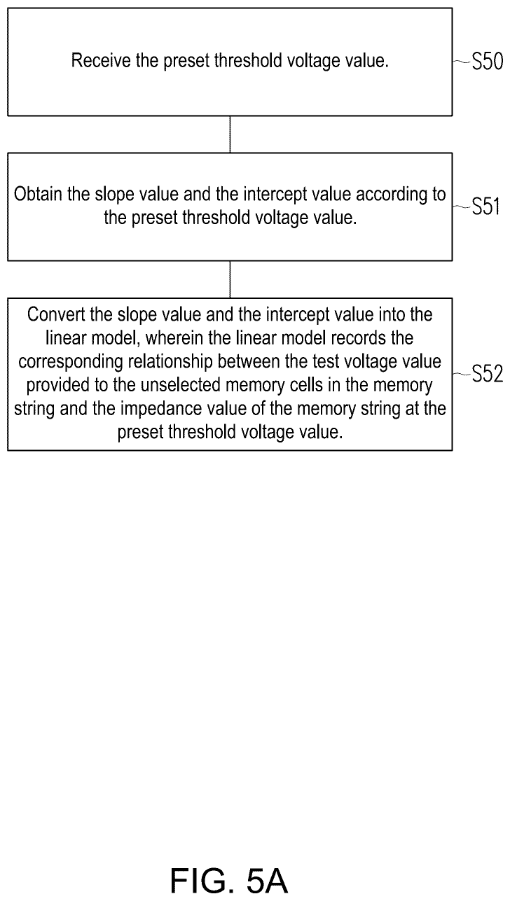

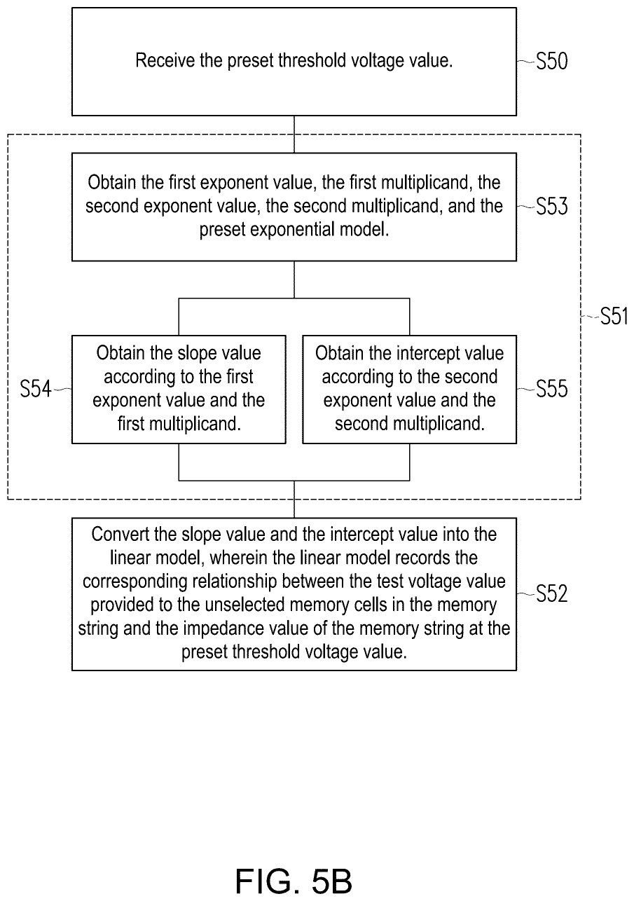

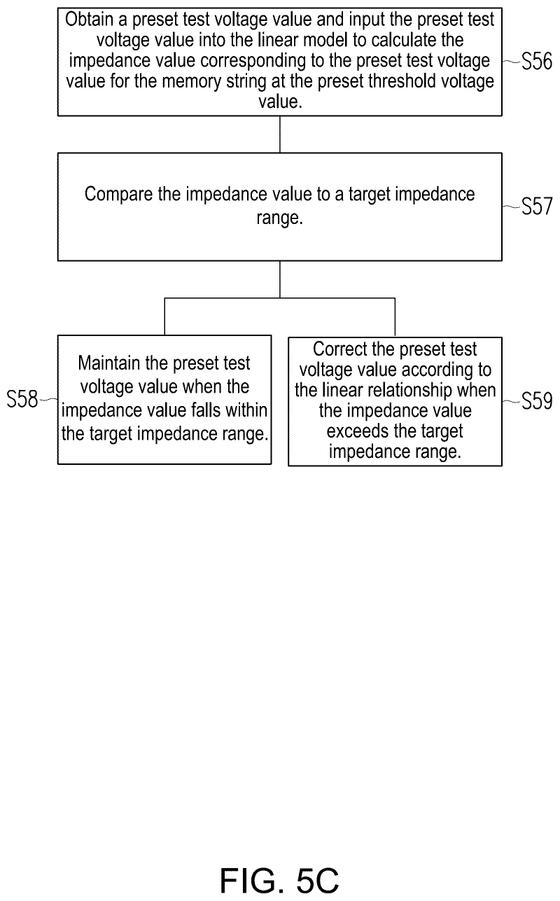

The memory circuit simulation method in FIG. 5A may be, for example, used to simulate the electrical behavior and performance of a memory string MS, such as the memory string MS in FIG. 2. The memory circuit simulation method in FIG. 5A includes steps S50 to S53. In step S50, the preset threshold voltage value is received. In step S51, the slope value and the intercept value are obtained according to the preset threshold voltage value. In step S52, the slope value and the intercept value are used to construct a linear model, which represents the relationship between the test voltage value applied to the unselected memory cells in the memory string and the impedance value of the memory string at the preset threshold voltage value.

Specifically, in step S51, the received preset threshold voltage value may, for example, be the voltage level to which the selected memory cell MC5 in the memory string MS is programmed.

In step S52, the relationship between the impedance value of the memory string MS and the pass voltage can be obtained under the condition that the selected memory cell MC5 has the preset threshold voltage value. For example, the relationship between the test voltage value and the corresponding first impedance value may be linear, and the linear characteristics vary depending on the threshold voltage of the selected memory cell MC5. Therefore, after receiving the preset threshold voltage value, the corresponding linear model may be obtained, for example, through a lookup table or other suitable methods. More specifically, since the linear model can be represented by the slope value and the intercept value, obtaining the linear model corresponding to the preset threshold voltage value involves retrieving the slope value and the intercept value of the linear model, and then substituting the slope value and the intercept value into the preset linear model for reconstruction. The preset linear model is:

$$R = P 1 \times V pass + P 2$$

wherein R corresponds to the impedance value of the memory string MS, Vpass corresponds to the pass voltage, P1 corresponds to the slope value of the linear model, and P2 corresponds to the intercept value of the linear model. Therefore, after substituting the slope value and intercept value into the preset linear model, the relationship between the impedance value of the memory string MS and the pass voltage (a type of the test value) can be reconstructed as a linear equation.

FIG. 5B is similar to FIG. 5A, except that the memory circuit simulation method in FIG. 5B not only includes steps S50 to S52, but also includes steps S53 to S55, which are executed as a part of step S51.

Specifically, in step S53, the first exponent value, the first multiplicand, the second exponent value, the second multiplicand, and the preset exponential model may be obtained. The first exponent value, the first multiplicand, the second exponent value, and the second multiplicand serve as coefficients in the preset exponential model. The first exponent value and the first multiplicand may be coefficients in the preset exponential model corresponding to the slope value, and the second exponent value and the second multiplicand may be coefficients in the preset exponential model corresponding to the intercept value. The preset exponential model is:

$$PX = C 1 \times {e}^{Vt \times C 2}$$

wherein when PX corresponds to the slope value, C1 corresponds to the first multiplicand, Vt corresponds to the preset threshold voltage value, and C2 corresponds to the first exponent value. When PX corresponds to the intercept value, C1 corresponds to the second multiplicand, Vt corresponds to the preset threshold voltage value, and C2 corresponds to the second exponent value. This way, after obtaining the first exponent value, the first multiplicand, the second exponent value, the second multiplicand, and the preset exponential model, the first exponent value and the first multiplicand may be substituted into the preset exponential model to derive the exponential model representing the variation of the slope value with respect to the threshold voltage. Moreover, the second exponent value and the second multiplicand may be substituted into the preset exponential model to derive another exponential model representing the variation of the intercept value with respect to the threshold voltage.

In step S54, the slope value is obtained according to the first exponent value and the first multiplicand. Specifically, in step S53, the exponential model representing the variation of the slope value with respect to the threshold voltage has already been obtained based on the first exponent value and the first multiplicand. Therefore, in step S54, the preset threshold voltage may be substituted into the exponential model to calculate the slope value of the linear relationship between the impedance value of the memory string MS and the pass voltage under that the preset threshold voltage value.

In step S55, the intercept value is obtained based on the second exponent value and the second multiplicand. Specifically, in step S53, the exponential model representing the variation of the intercept value with respect to the threshold voltage has already been derived using the second exponent value and the second multiplicand. Therefore, in step S55, the preset threshold voltage may be substituted into this exponential model to calculate the intercept value of the linear relationship between the impedance value of the memory string MS and the pass voltage under the preset threshold voltage value.

Overall, steps S53 to S55 may be summarized as the process for obtaining the slope value and the intercept value of the linear relationship between the impedance value of the memory string MS and the pass voltage, based on the preset threshold voltage value and the preset exponential model. Upon completion of steps S53 to S55, step S52 may then be executed to convert the slope value and the intercept value into the linear model.

FIG. 5C follows step S52 from either FIG. 5A or FIG. 5B. More specifically, through the memory circuit simulation method in FIG. 5C, the pass voltage applied to the unselected memory cells MC1 to MC4 and MC6 to MC8 in the memory string MS may be corrected according to the linear model obtained in step S52. The memory circuit simulation method in FIG. 5C includes steps S56 to S59.

In step S56, a preset test voltage value is obtained and input into the linear model to predict the impedance value of the memory string MS, under the condition that the selected memory cell MC5 is programmed to the preset threshold voltage value. Specifically, the preset test voltage value can refer to the pass voltage intended to be applied to the unselected memory cells MC1 to MC4 and MC6 to MC8 in the memory string MS. Accordingly, by substituting the preset test voltage value into the linear model, the circuit behavior of the memory string MS applied with the preset test voltage value under the condition that the selected memory cell MC5 is programmed to the preset threshold voltage value can be simulated by obtaining the impedance value of the memory string MS.

In step S57, the impedance value corresponding to the preset test voltage value may be compared to a target impedance range to determine if the impedance value falls within the target impedance range. More specifically, the target impedance range may refer to, for example, a system-defined specification or an expected impedance range for the memory string MS with the selected memory cell MC5 at the threshold voltage value. Therefore, if it is determined that the impedance value corresponding to the preset test voltage value falls within the target impedance range, step S58 is executed to maintain the preset test voltage value. However, if it is determined that the impedance value corresponding to the preset test voltage value does not fall within or exceeds the target impedance range, step S59 is executed to correct (adjust) the preset test voltage value according to the linear relationship.

Specifically, in step S59, an endpoint within the target impedance range, which is closer to the measured impedance value among endpoints, may be substituted into the linear relationship, and the corrected test voltage value is obtained through the linear relationship. The corrected test voltage value is then applied as the pass voltage to the unselected memory cells MC1 to MC4 and MC6 to MC8 in the memory string MS.

This way, through the memory circuit simulation method in FIG. 5C, individual memory may be simulated before leaving the factory. Thus, the pass voltages applied to unselected memory cells under different conditions are further adjusted to improve data accuracy in the memory system, ensuring correctness.

In an embodiment, the memory circuit simulation method in FIGS. 5A to 5C may be realized using a computer device, and the computer device may include a processor and memory. The computer device may store the first exponent value, the first multiplicand, the second exponent value, the second multiplicand, and the preset exponential model to predict the impedance value of the memory string MS applied with the preset test voltage value under the condition that the selected memory cell MC5 is programmed to the preset threshold voltage value.

The memory circuit simulation method in FIGS. 5A and 5B may be executed using, for example, simulation program with integrated circuit emphasis (SPICE), or similar circuit software such as H-Spice, P-Spice, Cadence, Advanced Design System (ADS), or other suitable circuit software.

The processor in the computer device used to execute the memory model building method in FIGS. 3A and 3B or the memory circuit simulation method in FIGS. 5A to 5C may be a central processing unit (CPU), or other programmable general-purpose or specific-purpose microcontroller units (MCU), microprocessors, digital signal processors (DSP), programmable controllers, application-specific integrated circuits (ASIC), graphics processing units (GPU), arithmetic logic units (ALU), complex programmable logic devices (CPLD), field-programmable gate arrays (FPGA), any other type of integrated circuits, state machines, ARM-based processors, or other similar elements or a combination of the above elements. Additionally, the memory in the computer device may be, for example, any type of fixed or removable random access memory (RAM), read-only memory (ROM), flash memory, hard disk drive (HDD), solid-state drive (SSD), or similar elements or combinations of the above elements, and be used to store steps, instructions, modules, or various applications that can be executed by the processor.

In summary, the memory model building method of the disclosure can analyze the relationship between impedance values of the memory string and the threshold voltage, and summarize the relationship into multiple coefficients and a single model or a small number of models, thereby showing the impedance changes of the memory string under all threshold voltage values. Correspondingly, the memory circuit simulation method can convert the coefficients and models into accurate circuit behavior of the memory string. Moreover, the memory circuit simulation method can further correct the pass voltage applied to the unselected memory cells, effectively improving the accuracy of memory circuit operation. Therefore, the methods can effectively reduce the complexity of the circuit model, lower the storage space required for the memory model, decrease the time needed for circuit simulation, and improve the accuracy of circuit simulation.

What is claimed is:

1. A memory model building method, comprising:
applying a test condition to a plurality of unselected memory cells in a memory string, wherein a threshold voltage of a selected memory cell in the memory string is programmed to a first threshold voltage value;
by setting the test condition as a plurality of test values, performing a plurality of tests on the memory string so as to obtain a plurality of first impedance values respectively corresponding to the plurality of test values; and
analyzing the plurality of test values and the plurality of respective corresponding first impedance values to obtain a linear model having a first slope value and a first intercept value, wherein a corresponding relationship between the plurality of test values and the plurality of respective corresponding first impedance values at the first threshold voltage value satisfies the linear model.

2. The memory model building method according to claim 1, wherein the test condition is a test voltage, a test temperature, or a combination thereof.

3. The memory model building method according to claim 1, wherein the linear model is:
$$R = P 1 \times V pass + P 2$$
wherein R corresponds to each of the plurality of first impedance values, Vpass corresponds to each of the plurality of test values, P1 corresponds to the first slope value, and P2 corresponds to the first intercept value.

4. The memory model building method according to claim 1, further comprising:
programming the selected memory cell according to a second threshold voltage value;
by setting the test condition applied to the plurality of unselected memory cells as the plurality of test values, performing the plurality of tests on the memory string so as to obtain a plurality of second impedance values; and
analyzing the plurality of test values and the plurality of respective corresponding second impedance values to obtain a second slope value and a second intercept value of the linear model satisfied by the plurality of test values and the plurality of second impedance values at the second threshold voltage value.

5. The memory model building method according to claim 4, wherein the first threshold voltage value and the second threshold voltage value satisfy an exponential model, the memory model building method further comprising:
analyzing the first slope value and the second slope value to obtain a first exponent value and a first multiplicand in the exponential model; and
analyzing the first intercept value and the second intercept value to obtain a second exponent value and a second multiplicand in the exponential model.

6. The memory model building method according to claim 5, wherein the exponential model is:
$$PX = C 1 \times {e}^{Vt \times C 2}$$
wherein when PX corresponds to the first slope value or the second slope value, C1 corresponds to the first multiplicand, Vt corresponds to the set first threshold voltage value or the second threshold voltage value of the selected memory cell, and C2 corresponds to the first exponent value,
wherein when PX corresponds to the first intercept value or the second intercept value, C1 corresponds to the second multiplicand, Vt corresponds to the set first threshold voltage value or the second threshold voltage value of the selected memory cell, and C2 corresponds to the second exponent value.

7. A memory circuit simulation method for simulating a circuit behavior of a memory string having a plurality of unselected memory cells and a selected memory cell, the memory circuit simulation method comprising:
receiving a preset threshold voltage value;
obtaining a slope value and an intercept value according to the preset threshold voltage value; and
converting the slope value and the intercept value into a linear model, wherein the linear model records a corresponding relationship between a test value provided to the plurality of unselected memory cells in the memory string and an impedance value of the memory string at the preset threshold voltage value.

8. The memory circuit simulation method according to claim 7, wherein the test value is a test voltage value, a test temperature value, or a combination thereof.

9. The memory circuit simulation method according to claim 7, wherein the linear model is:
$$R = P 1 \times V pass + P 2$$
wherein R corresponds to the impedance value, Vpass corresponds to the test value, P1 corresponds to the slope value, and P2 corresponds to the intercept value.

10. The memory circuit simulation method according to claim 7, wherein obtaining the slope value and the intercept value according to the preset threshold voltage value comprises:
according to the preset threshold voltage value and a preset exponential model, obtaining the slope value and the intercept value.

11. The memory circuit simulation method according to claim 10, further comprising:
substituting a first exponent value, a first multiplicand, and the preset threshold voltage value into the preset exponential model to obtain the slope value; and
substituting a second exponent value, a second multiplicand, and the preset threshold voltage value into the preset exponential model to obtain the intercept value.

12. The memory circuit simulation method according to claim 11, wherein the preset exponential model is:
PX=C1×e^{Vt×C2}
wherein when PX corresponds to the slope value, C1 corresponds to the first multiplicand, Vt corresponds to the preset threshold voltage value, and C2 corresponds to the first exponent value,
wherein when PX corresponds to the intercept value, C1 corresponds to the second multiplicand, Vt corresponds to the preset threshold voltage value, and C2 corresponds to the second exponent value.

13. The memory circuit simulation method according to claim 7, after converting the slope value and the intercept value into the linear model, further comprising:
obtaining a preset test value and inputting the preset test value into the linear model to obtain the impedance value corresponding to the preset test value for the memory string at the preset threshold voltage value.

14. The memory circuit simulation method according to claim 13, further comprising:
comparing the impedance value to a target impedance range;
when the impedance value falls within the target impedance range, maintaining the preset test value; and
when the impedance value falls outside the target impedance range, modifying the preset test value according to a linear relationship.

15. The memory circuit simulation method according to claim 14, wherein modifying the preset test value according to the linear relationship comprises:
substituting one of at least one endpoint of the target impedance range closest to the impedance value into the linear relationship to obtain a modified test value.
